(19) United States
(12) Patent Application Publication
(10) Pub. No.: US 2026/0035237 A1
(43) Pub. Date: Feb. 5, 2026

(54) MICROSTRUCTURE WITH HIGH BONDING STRENGTH AND FORMATION METHOD THEREOF

(71) Applicant: Geeder company Limited, Taichung City (TW)

(72) Inventors: CHENG-SHENG TSUNG, Taichung City (TW); Shao-Wen Hung, Taichung City (TW)

(21) Appl. No.: 18/793,989

(22) Filed: Aug. 5, 2024

(51) Int. Cl. B81C 1/00; G02B 5/00

(52) U.S. Cl. CPC B81C 1/00031; G02B 5/008; B81C 2201/0176; B81C 2201/0181; B81C 2201/019

(57) ABSTRACT

A microstructure with high bonding strength includes a substrate, a deposition layer, and a first dielectric layer. The substrate has a first surface. The first surface has a covered area and an exposed area. The deposition layer has a plurality of nanoscale metal particles. The deposition layer is disposed on the covered area of the first surface. The exposed area is exposed from the deposition layer. The deposition layer has a bonding face on one side away from the first surface. The first dielectric layer is disposed on the bonding face and contacts the exposed area. With the connection structure between the first dielectric layer and the exposed area of the substrate, a hotspot structure formed by the deposition layer and the first dielectric layer is more stably fixed to the substrate, thereby improving bonding strength of the overall structure.

### BACKGROUND OF THE INVENTION

### 1. Field of the Invention

The present invention relates to a microstructure and formation method thereof, and more particularly, to a microstructure with high bonding strength and formation method thereof.

### 2. Description of the Related Art

In the current field of photoelectricity, many photoelectric products (such as solar cell systems, optical sensor structures, biosensors, etc.) utilize microstructures capable of forming surface plasmas to enhance the overall performance of photoelectric products.

Currently existing microstructures are typically stacked structures formed by multiple stacked up structural layers. However, in such microstructures, the structural layers are combined in a heterogeneous contact manner, causing a lower combination stability between the structural layers, such that the microstructure is subject to issues such as low overall structural strength and short service life, as well as consumption of plasmons energy, leading to an unstable and inadequate performance. Such issues seriously impact the effectiveness of products, and may also reduce product yield during manufacturing process, adding unnecessary costs.

### SUMMARY OF THE INVENTION

The present invention aims at resolving the issues of the conventional microstructure having low overall structural strength and short service life.

To achieve the objectives above, an embodiment of the present invention provides a microstructure with high bonding strength, comprising a substrate, a deposition layer, and a first dielectric layer. The substrate has a first surface; the first surface has a covered area and an exposed area. The deposition layer has a plurality of nanoscale metal particles. The deposition layer is disposed on the covered area of the first surface. The exposed area is exposed from the deposition layer. The deposition layer has a bonding face on one side thereof away from the first surface. The first dielectric layer is disposed on the bonding face and contacts the exposed area.

In another embodiment of the present invention, the nanoscale metal particles form a crystal themselves or in interaction with surrounding substance molecules. A surface plasmon polariton is generated on the surface of the nanoscale metal particles. Also, a Tamm plasmon polariton is formed at the interface or lattice discontinuities within the crystal. The surface plasmon polariton and the Tamm plasmon polariton resonate to create an optical Tamm state.

In another embodiment, the nanoscale metal particles of the covered area form a hotspot structure with the first dielectric layer and the substrate through eutectic and bonding. The first dielectric layer of the exposed area is connected with the substrate by contacting the substrate to form a connection structure.

In an embodiment of the present invention, a method of forming a microstructure with high bonding strength is provided, comprising following steps: a substrate providing step:

providing a substrate, a first surface of the substrate having a covered area and an exposed area; a deposition layer forming step: forming a deposition layer having a plurality of nanoscale metal particles on the covered area of the first surface, so that the exposed area is exposed from the deposition layer, wherein the deposition layer is formed through a method selected from a group consisting of spray coating, immersion coating, blade coating, roll coating, adsorption, and spin coating; and a first dielectric layer forming step: forming a first dielectric layer on a bonding face of the deposition layer away from the first surface, so that the first dielectric layer is connected with the exposed area.

In another embodiment of the present invention, in the first dielectric layer forming step, the nanoscale metal particles of the covered area form a hotspot structure with the first dielectric layer and the substrate through eutectic and bonding. The first dielectric layer of the exposed area is connected with the substrate by contacting the substrate to form a connection structure.

In another embodiment of the present invention, another method of forming a microstructure with high bonding strength is provided, comprising following steps: a substrate providing step: providing a substrate, the substrate having a first surface; a deposition layer forming step: forming a deposition layer having a plurality of nanoscale metal particles on the first surface of the substrate, wherein the deposition layer is formed through a method selected from a group consisting of physical vapor deposition (PVD) and chemical vapor deposition (CVD); and a first dielectric layer forming step: forming a first dielectric layer on a bonding face of the deposition layer away from the first surface, and forming an exposed area exposed from the deposition layer on the first surface through a high-energy destruction method, so that the first dielectric layer is connected with the exposed area.

In another embodiment of the present invention, in the first dielectric layer forming step, the nanoscale metal particles of the covered area form a hotspot structure with the first dielectric layer and the substrate through eutectic and bonding. The first dielectric layer of the exposed area is connected with the substrate by contacting the substrate to form a connection structure.

With such configuration of the present invention, the connection structure between the first dielectric layer and the exposed area of the substrate allows the hotspot structure formed by the deposition layer and the first dielectric layer to be more stably fixed to the substrate. Also, due to the eutectic and bonding involving the nanoscale metal particles and the dielectric layer material, the connection structure and the hotspot structure are more stable, thereby achieving the objective of improving the bonding strength of the overall structure.

Also, the nanoscale metal particles within the deposition layer and the material of the first dielectric layer form a large number of crystals to form the hotspot structure. The nanoscale metal particles are capable of generating surface plasmon polaritons, and Tamm plasmon polaritons are formed at interfaces or lattice discontinuities within the crystals, so that the primary generation areas of the surface plasmon polaritons and the Tamm plasmon polaritons, such that the framework of the connection structure and the hotspot structure form a more stable optical Tamm state, which leads to increased efficiency in light emission or light detection. Additionally, the gradual decrease in the metal density within the hotspot structure from the inside toward the outside allows a directional release of energy of the optical Tamm state from the areas with high metal content to those with low metal content, significantly reducing energy consumption caused by non-directionality, thereby maximizing the structural malleability.

### BRIEF DESCRIPTION OF THE DRAWINGS

FIG. 1 is a sectional view of the microstructure with high bonding strength in accordance with an embodiment of the present invention.

FIG. 2 is a sectional view of the microstructure with high bonding strength in accordance with another embodiment of the present invention, illustrating the substrate having a substrate layer and a second dielectric layer.

FIG. 3 is a partially perspective view of the microstructure with high bonding strength in accordance with an embodiment of the present invention, illustrating the exposed area exposed from the deposition layer.

FIG. 4 is a flow chart of the formation method of the microstructure with high bonding strength in accordance with an embodiment of the present invention.

FIG. 5 is a flow chart of the formation method of the microstructure with high bonding strength in accordance with an embodiment of the present invention, illustrating a further included reaction step.

FIG. 6 is a sectional view of the microstructure with high bonding strength in accordance with another embodiment of the present invention.

FIG. 7 a sectional view of the microstructure with high bonding strength in accordance with another embodiment of the present invention, illustrating the substrate having a substrate layer and a second dielectric layer.

FIG. 8 is a partially perspective view of the microstructure with high bonding strength in accordance with another embodiment of the present invention, illustrating the exposure bore of the deposition layer.

FIG. 9. is a flow chart of the formation method of the microstructure with high bonding strength in accordance with a second embodiment of the present invention.

FIG. 10 is a flow chart of the formation method of the microstructure with high bonding strength in accordance with the second embodiment of the present invention, illustrating a further included reaction step.

### DETAILED DESCRIPTION OF THE INVENTION

The aforementioned and further advantages and features of the present invention will be understood by reference to the description of the preferred embodiment in conjunction with the accompanying drawings where the components are illustrated based on a proportion for explanation but not subject to the actual component proportion.

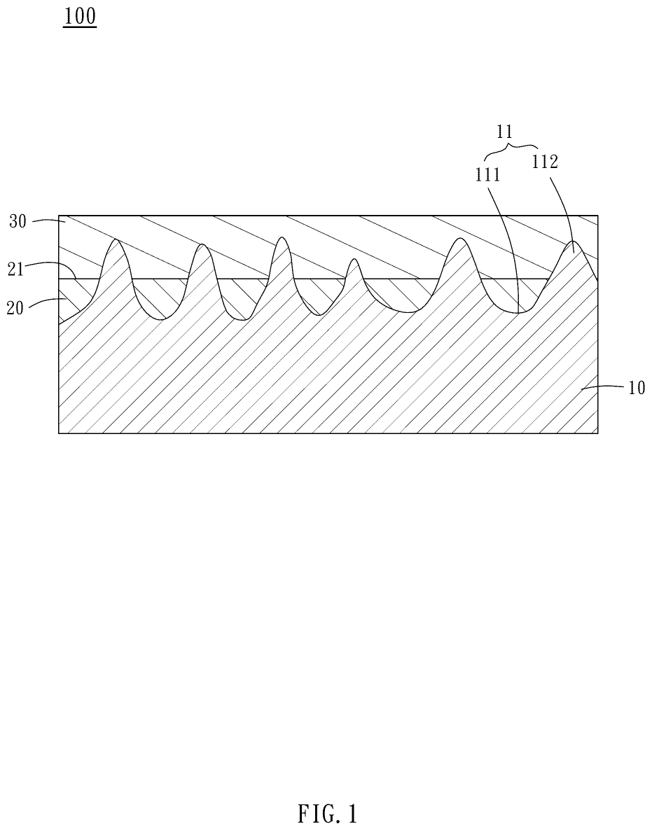

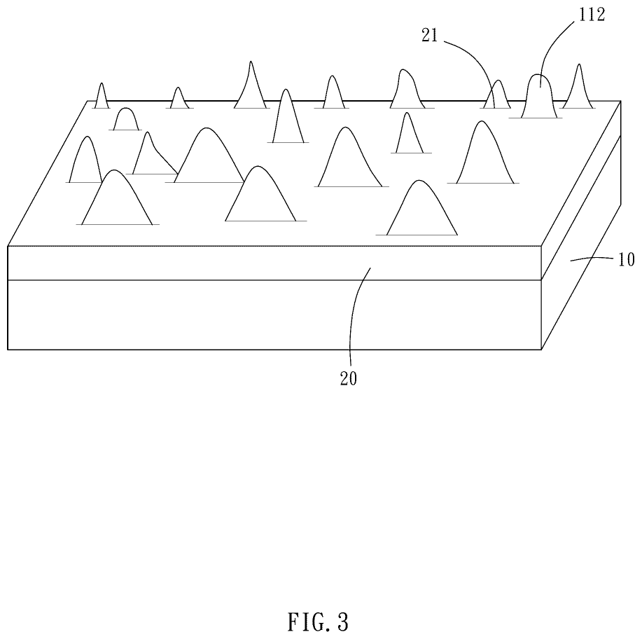

Referring to FIG. 1 to FIG. 3, the present invention discloses a microstructure 100 with high bonding strength, comprising a substrate 10, a deposition layer 20, and a first dielectric layer 30.

The substrate 10 comprises a first surface 11. The first surface 11 comprises a covered area 111 and an exposed area 112. Therein, the substrate 10 is formed of material selected from, for example but not limited to, gallium nitride, aluminum oxide, silicon, and silicon oxide. The material of the substrate 10 is also allowed to be selected based on the intended application, such as for solar cells, optical sensors, light-emitting diodes, or other optoelectronic components, or as a base for single or composite film layers. Notably, in order to emphasize the structural differences between the covered area 111 and the exposed area 112, the height differences and sharpness depicted for showing the covered area 111 and the exposed area 112 in FIG. 1 to FIG. 3 are for illustrative purposes only. In reality, the shapes of those areas may be flatter, and the exposed area 112 may also be a raised flat area. However, it should be understood that as long as there is a height difference between the covered area 111 and the exposed area 112, the depiction fulfills the definition in this embodiment.

The deposition layer 20 comprises a plurality of nanoscale metal particles. The deposition layer 20 is disposed on the covered area 111 of the first surface 11. The exposed area 112 is exposed from the deposition layer 20. The deposition layer 20 has a bonding face 21 on one side thereof away from the first surface 11. Therein, the nanoscale metal particles are allowed to be nanoscale metallic materials or metallic compound materials. The metallic materials are allowed to be metals, such as gold, silver, copper, iron, platinum, palladium, aluminum, titanium, vanadium, chromium, nickel, tantalum, tungsten, tin, gallium, cobalt, lithium, sodium, magnesium, calcium, and others. The metallic compound materials are allowed to be conductive metal oxides, such as gallium arsenide, indium phosphide, indium oxide, indium tin oxide, indium gallium zinc oxide, fluorine-doped tin oxide, silicon-doped zinc oxide, and others. In addition, in another embodiment, the deposition layer 20 is also allowed to be formed from multiple nanoscale metal films stacked up.

The first dielectric layer 30 is disposed on the bonding face 21 and contacts the exposed area 112. Therefore, the connection between the first dielectric layer 30 and the exposed area 112 of the substrate 10 allows the deposition layer 20 to be more stably fixed between the substrate 10 and the first dielectric layer 30, so as to form the microstructure 100 with high bonding strength of the present invention.

In an embodiment of the present invention, the nanoscale metal particles in the deposition layer 20 form a crystal themselves or in interaction with surrounding substance molecules. The surrounding substance molecules are allowed to be, for example, the substrate 10 or the first dielectric layer 30. A surface plasmon polariton (SPP) is generated on the surface of the nanoscale metal particles. Also, a Tamm plasmon polariton (TPP) is formed at the interface or lattice discontinuities within the crystal. The surface plasmon polariton and the Tamm plasmon polariton resonate to create an optical Tamm state (OTS).

Referring to FIG. 1 to FIG. 6, in an embodiment, the nanoscale metal particles of the covered area 111 form a hotspot structure 40 with the first dielectric layer 30 and substrate 10 through eutectic and bonding. The first dielectric layer 30 of the exposed area 112 contacts the substrate 10 to form a connection structure 50.

Therein, using the gradient variation in the metal content caused by the covered area 111 and the exposed area 112, the primary generation areas of the surface plasmon polaritons and the Tamm plasmon polaritons are confined, and the framework of the hotspot structure 40 forms a more stable optical Tamm state. Also, the gradual decrease in the gradient of metal content within the hotspot structure 40 from the inside toward the outside allows a directional release of energy of the optical Tamm state from the areas with high metal content to those with low metal content, significantly reducing energy consumption caused by non-directionality, thereby maximizing the structural malleability.

Furthermore, the size of the connection structure 50 varies according to the size of the exposed area 112. When the concentration of the nanoscale metal particles of the deposition layer 20 is lower, the deposition layer 20 is formed with smaller thickness and the measure of area of the exposed area 112 is larger. Therefore, the contact area between the first dielectric layer 30 and the substrate 10 is larger, causing the connection structure 50 to form a larger number of smaller-sized thin pillar structures. When the concentration of the nanoscale metal particles of the deposition layer 20 is higher, the deposition layer 20 is formed with larger thickness and the measure of area of the exposed area 112 is smaller. Therefore, the contact area between the first dielectric layer 30 and the substrate 10 is smaller, causing the connection structure 50 to form a smaller number of larger-sized thick pillar structures. Thus, the connection structure 50 allows the structure of the present invention to have a higher structural strength and malleability.

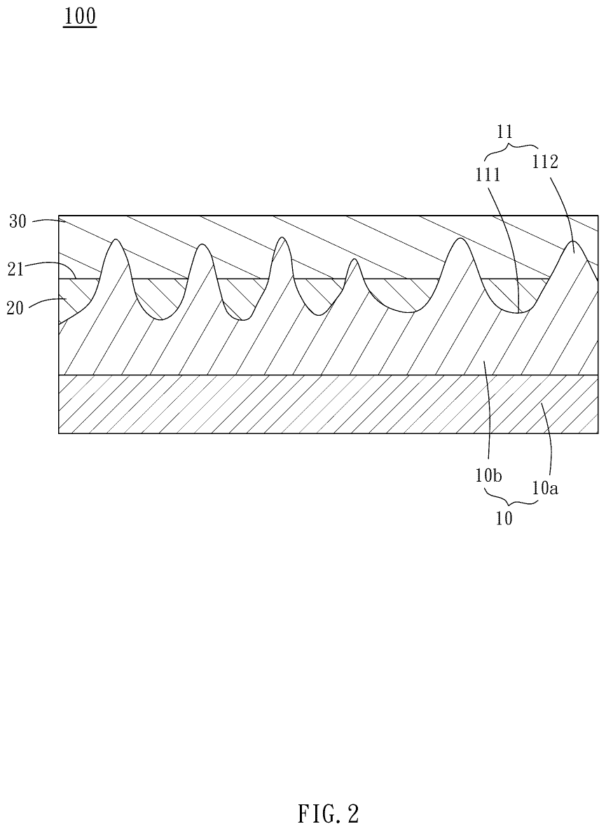

In another embodiment of the present invention, referring to FIG. 2, the substrate 10 comprises a substrate layer 10a and a second dielectric layer 10b. The second dielectric layer 10b is disposed on one side of the substrate layer 10a in adjacent to the deposition layer 20. The second dielectric layer 10b comprises a first surface 11 on one side away from the substrate layer 10a. The exposed area 112 of the second dielectric layer 10b is connected with the first dielectric layer 30. Therefore, because the first dielectric layer 30 and the second dielectric layer 10b are allowed to be formed with same material, the first dielectric layer 30 and the second dielectric layer 10b have a higher bonding strength, further enhancing the structural strength of the present invention. Also, the nanoscale metal particles of the deposition layer 20 are able to move toward the first dielectric layer 30 and the second dielectric layer 10b, respectively, so as to form a broader range of the optical Tamm state structure.

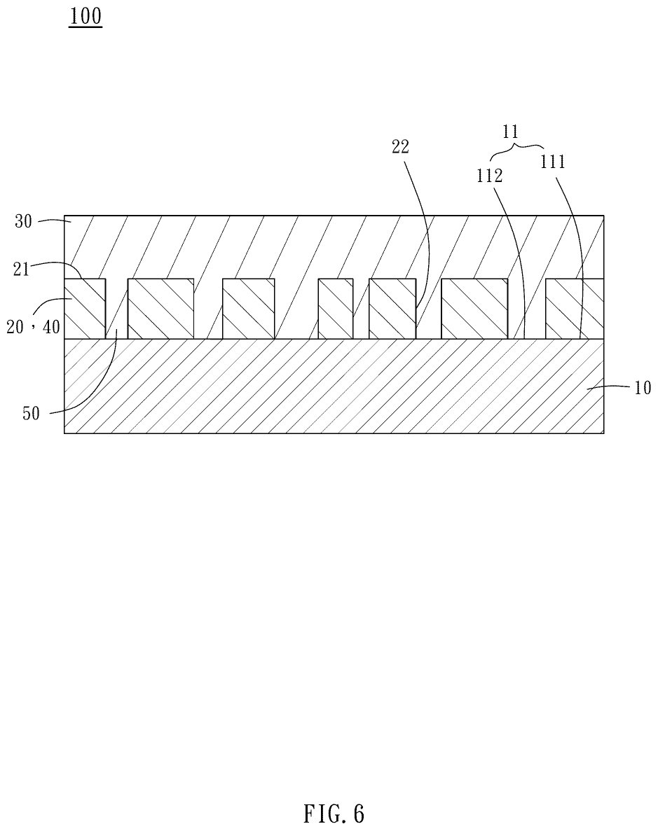

Also, referring to FIG. 2 and FIG. 6, the nanoscale metal particles of the covered area 111 form the hotspot structure 40 with the first dielectric layer 30 and the second dielectric layer 10b through eutectic and bonding. The first dielectric layer 30 of the exposed area 112 contacts the second dielectric layer 10b to form the connection structure 50.

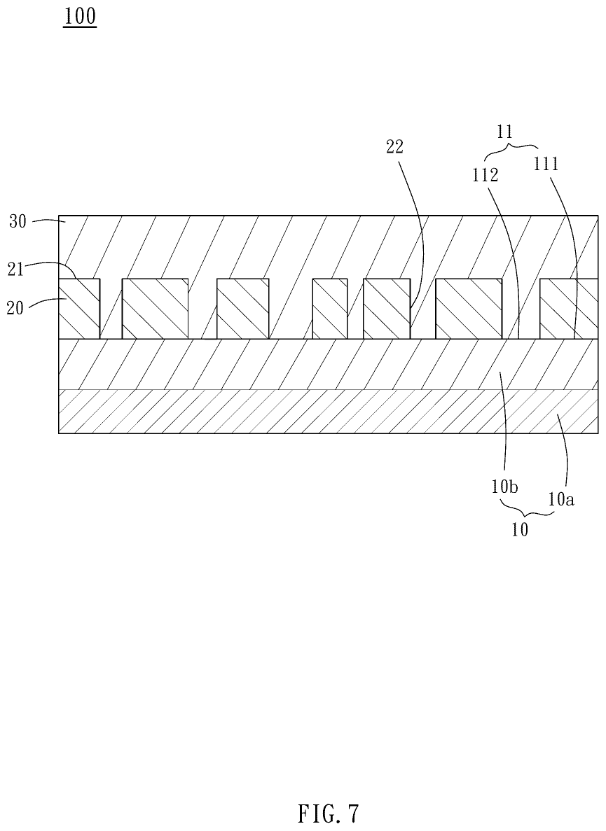

Furthermore, referring to FIG. 6 to FIG. 8, in another embodiment, if the first surface 11 of the substrate 10 is formed in a flat shape, the deposition layer 20 has multiple exposure bores 22. The exposure bores 22 allow parts of the first surface 11 to be exposed from the deposition layer 20, so as to form the exposed area 112. The first dielectric layer 30 is filled in the exposure bores 22 and connected with the exposed area 112 to form the microstructure 100 with high bonding strength of the present invention. With such configuration, the additional sidewall areas of the exposure bores 22 further facilitate the eutectic and bonding between the nanoscale metal particles of the deposition layer 20 and the dielectric material of the first dielectric layer 30, thereby increasing the bonding strength.

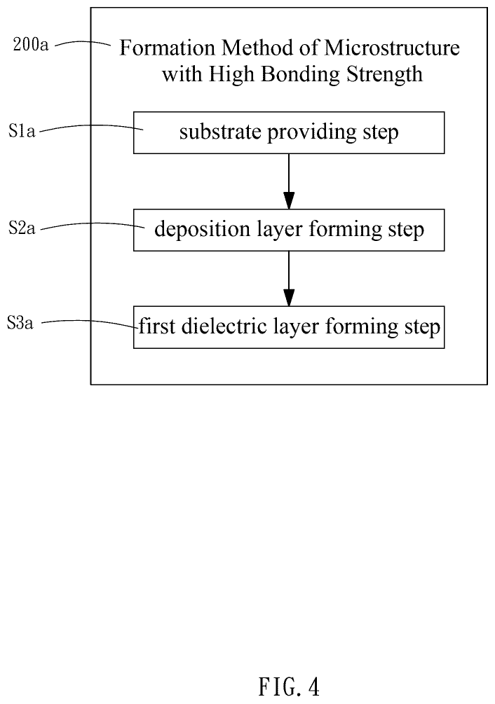

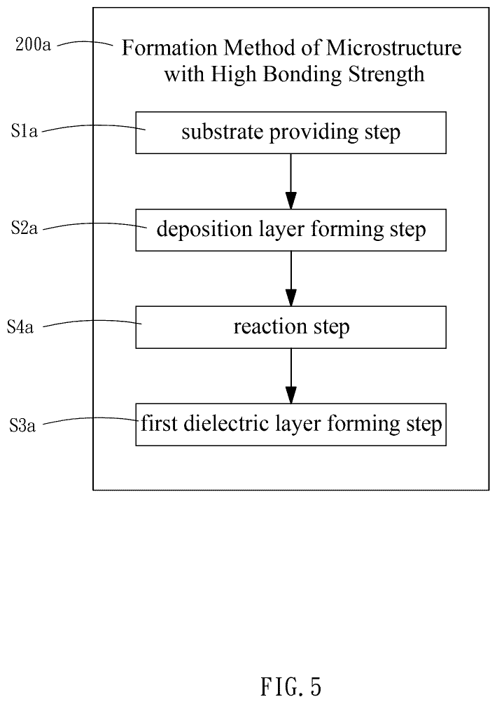

Referring to FIG. 4 to FIG. 5, to manufacture the aforementioned microstructure 100, the present invention provides a formation method 200a of the microstructure 100 with high bonding strength, comprising a substrate providing step S1a, a deposition layer forming step S2a, and a first dielectric layer forming step S3a.

In the substrate providing step S1a, the substrate 10 is provided. The first surface 11 of the substrate 10 comprises the covered area 111 and the exposed area 112. Therein, the substrate 10 is formed of material selected from, for example but not limited to, gallium nitride, aluminum oxide, silicon, and silicon oxide. The material of the substrate 10 is also allowed to be selected based on the intended application, such as for solar cells, optical sensors, light-emitting diodes, or other optoelectronic components, or as a base for single or composite film layers.

In the deposition layer forming step S2a, the deposition layer 20 comprising the plurality of nanoscale metal particles is formed on the covered area 111 of the first surface 11, so that the exposed area 112 is exposed from the deposition layer 20. Therein, the deposition layer 20 is formed through a method selected from a group consisting of spray coating, immersion coating, blade coating, roll coating, adsorption, and spin coating. With such method, during the formation process of the deposition layer 20, the exposed area 112 is directly exposed and prevented from being covered by the deposition layer 20.

In the embodiment of the present invention, the nanoscale metal particles are allowed to be nanoscale metallic materials or metallic compound materials. The metallic materials are allowed to be metals, such as gold, silver, copper, iron, platinum, palladium, aluminum, titanium, vanadium, chromium, nickel, tantalum, tungsten, tin, gallium, cobalt, lithium, sodium, magnesium, calcium, and others. The metallic compound materials are allowed to be conductive metal oxides, such as gallium arsenide, indium phosphide, indium oxide, indium tin oxide, indium gallium zinc oxide, fluorine-doped tin oxide, silicon-doped zinc oxide, and others.

In the first dielectric layer forming step S3a, the first dielectric layer 30 is formed on the bonding face 21 of the deposition layer 20 away from the first surface 11, and the first dielectric layer 30 is connected with the exposed area 112. Therein, pillar-shaped crystals are formed in the connection parts between the first dielectric layer 30 and the exposed area 112. Therefore, the pillar-shaped crystals improve the structure strength of the present invention.

Referring to FIG. 5, in the embodiment of the present invention, after the deposition layer forming step S2a or the first dielectric layer forming step S3a, a reaction step S4a is further included. In the reaction step S4a, the nanoscale metal particles form the crystal themselves or in interaction with surrounding substance molecules. The surface plasmon polariton is generated on the surface of the nanoscale metal particles. Also, the Tamm plasmon polariton is formed at the interface or lattice discontinuities within the crystal. The surface plasmon polariton and the Tamm plasmon polariton resonate to create an optical Tamm state.

Referring to FIG. 1, FIG. 4, and FIG. 6, in the embodiment of the present invention, in the first dielectric layer forming step S3a, the nanoscale metal particles of the covered area 111 form the hotspot structure 40 with the first dielectric layer 30 and the substrate 10 through eutectic and bonding. The first dielectric layer 30 of the exposed area 112 contacts the substrate 10 to form the connection structure 50.

Also, in another embodiment of the present invention, in the substrate providing step S1a, the substrate 10 comprises the substrate layer 10a and the second dielectric layer 10b. The second dielectric layer 10b comprises the first surface 11 on one side away from the substrate layer 10a. In the first dielectric layer forming step S3a, the first dielectric layer 30 is connected with the exposed area 112 of the second dielectric layer 10b. Therefore, because the first dielectric layer 30 and the second dielectric layer 10b are allowed to be formed with same material, the first dielectric layer 30 and the second dielectric layer 10b have a higher bonding strength, further enhancing the structural strength of the present invention. The hotspot structure 40 is formed of the nanoscale metal particles of the covered area 111, the first dielectric layer 30, and the second dielectric layer 10b through eutectic and bonding. The connection structure 50 is formed by the contact combination of the first dielectric layer 30 and the second dielectric layer 10b in the exposed area 112.

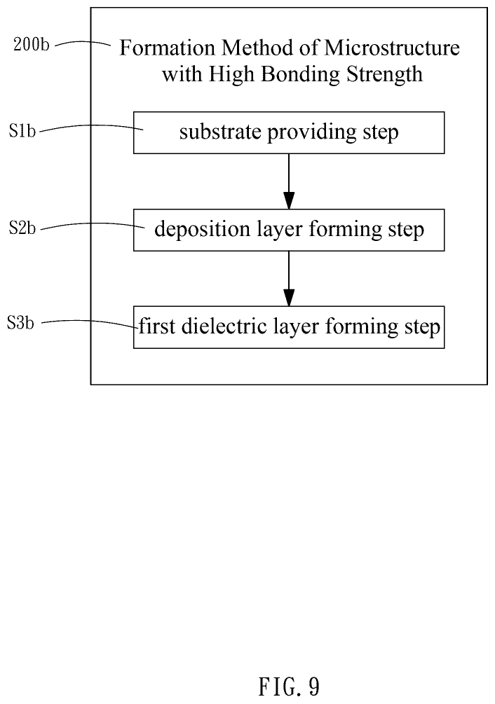

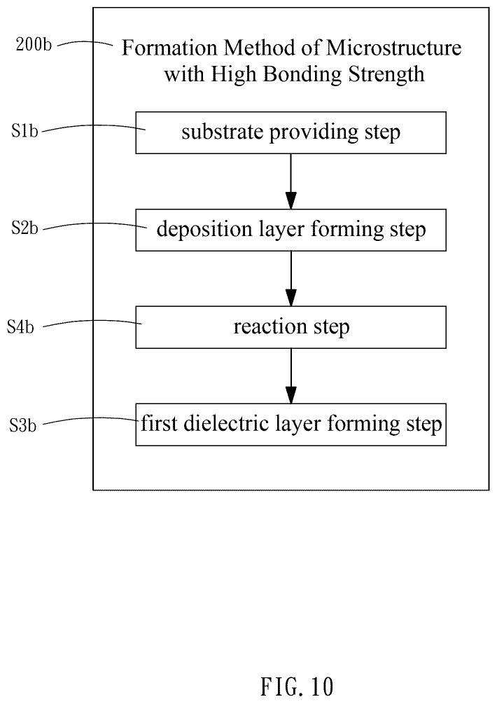

Referring to FIG. 9 and FIG. 10, the present invention provides another formation method 200b of the microstructure 100 with high bonding strength, comprising a substrate providing step S1b, a deposition layer forming step S2b, and a first dielectric layer forming step S3b.

In the substrate providing step S1b, the substrate 10 is provided. The substrate 10 has the first surface 11. Therein, the substrate 10 is formed of material selected from, for example but not limited to, gallium nitride, aluminum oxide, silicon, and silicon oxide. The material of the substrate 10 is also allowed to be selected based on the intended application, such as for solar cells, optical sensors, light-emitting diodes, or other optoelectronic components, or as a base for single or composite film layers.

In the deposition layer forming step S2b, the deposition layer 20 comprising the plurality of nanoscale metal particles is formed on the first surface 11. Therein, the deposition layer 20 is formed through a method selected from physical vapor deposition (PVD) and chemical vapor deposition (CVD). Accordingly, the deposition layer 20 completely covers the first surface 11 of the substrate 10.

In the embodiment of the present invention, the nanoscale metal particles are allowed to be nanoscale metallic materials or metallic compound materials. The metallic materials are allowed to be metals, such as gold, silver, copper, iron, platinum, palladium, aluminum, titanium, vanadium, chromium, nickel, tantalum, tungsten, tin, gallium, cobalt, lithium, sodium, magnesium, calcium, and others. The metallic compound materials are allowed to be conductive metal oxides, such as gallium arsenide, indium phosphide, indium oxide, indium tin oxide, indium gallium zinc oxide, fluorine-doped tin oxide, silicon-doped zinc oxide, and others.

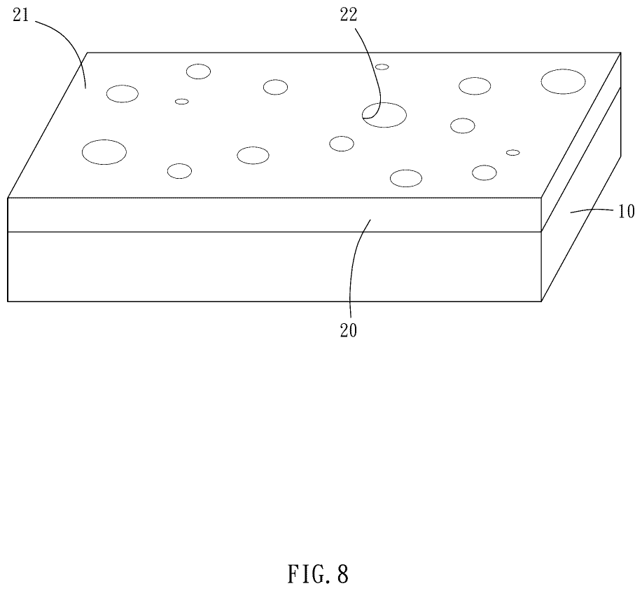

In the first dielectric layer forming step S3b, the first dielectric layer 30 is formed on the bonding face 21 of the deposition layer 20 away from the first surface 11, and the exposed area 112 is formed on the first surface 11 through a high-energy destruction method to be exposed from the deposition layer 20, so that the first dielectric layer 30 is connected with the exposed area 112. Therein, the height of the exposed area 112 formed through the high-energy destruction method is lower than the height of the deposition layer 20, so that the deposition layer 20 contains multiple bores (as shown by FIG. 8).

Furthermore, the exposed area 112 formed by high-energy destruction method is allowed to be formed by simply using the high-energy particles in the first dielectric layer 30 through the method of cohesion, bombardment, or activation. Alternatively, the exposed area 112 is allowed to be formed by using the high-energy particles together with the dielectric material in the first dielectric layer 30 through the method of cohesion, bombardment, or activation.

Referring to FIG. 6 and FIG. 9, in the embodiment of the present invention, in the first dielectric layer forming step S3b, the nanoscale metal particles of the covered area 111 form the hotspot structure 40 with the first dielectric layer 30 and the substrate 10 through eutectic and bonding. The first dielectric layer 30 of the exposed area 112 contacts the substrate 10 to form the connection structure 50.

Furthermore, referring to FIG. 6 to FIG. 8, in another embodiment, if the first surface 11 of the substrate 10 is formed in a flat shape, in the first dielectric layer forming step S3b, the deposition layer 20 is provided with multiple exposure bores 22 formed through the high-energy destruction method. The exposure bores 22 allow parts of the first surface 11 to be exposed from the deposition layer 20, so as to form the exposed area 112. The first dielectric layer 30 is filled in the exposure bores 22 and connected with the exposed area 112 to form the microstructure 100 with high bonding strength of the present invention. With such configuration, the additional sidewall areas of the exposure bores 22 further facilitate the eutectic and bonding between the nanoscale metal particles of the deposition layer 20 and the dielectric material of the first dielectric layer 30, thereby increasing the bonding strength.

Referring to FIG. 10, in the embodiment of the present invention, after the deposition layer forming step S2b or the first dielectric layer forming step S3b, a reaction step S4b is further included. In the reaction step S4b, the nanoscale metal particles form the crystal themselves or in interaction with surrounding substance molecules. The surface plasmon polariton is generated on the surface of the nanoscale metal particles. Also, the Tamm plasmon polariton is formed at the interface or lattice discontinuities within the crystal. The surface plasmon polariton and the Tamm plasmon polariton resonate to create an optical Tamm state.

Also, in another embodiment of the present invention, in the substrate providing step S1b, the substrate 10 comprises the substrate layer 10a and the second dielectric layer 10b. The second dielectric layer 10b comprises the first surface 11 on one side away from the substrate layer 10a. In the first dielectric layer forming step S3b, the first dielectric layer 30 is connected with the exposed area 112 of the second dielectric layer 10b. Therefore, because the first dielectric layer 30 and the second dielectric layer 10b are allowed to be formed with same material, the first dielectric layer 30 and the second dielectric layer 10b have a higher bonding strength, further enhancing the structural strength of the present invention. The hotspot structure 40 is formed of the nanoscale metal particles of the covered area 111, the first dielectric layer 30, and the second dielectric layer 10b through eutectic and bonding. The connection structure 50 is formed by the contact combination of the first dielectric layer 30 and the second dielectric layer 10b in the exposed area 112.

For example, if the present invention is to be used in the manufacturing of chemical substance sensors, the forming steps of the microstructure 100 with high bonding strength are as follows:

1. Aluminum oxide or silicon is taken as the substrate 10. Therein, the substrate 10 comprises the second dielectric layer 10b, which is a transparent conductive dielectric film containing indium tin oxide. The first surface 11 of the second dielectric layer 10b is prepared by evaporation or sputtering, and then undergoes an annealing process (with a 550 degrees Celsius annealing temperature) to have its surface roughness reduced, improving the film quality and reducing structural defects.

2. The substrate 10 is coated with nanoparticles of aluminum metal element or a nanoscale aluminum film as the deposition layer 20.

3. Parts of the deposition layer 20 are removed through a high-energy particle bombardment to form an indium tin oxide dielectric film, which is connected with the exposed area 112, as the first dielectric layer 30, thereby forming the microstructure 100 with high bonding strength.

4. The completed microstructure 100 with high bonding strength undergoes the annealing process again (with a 550 degrees Celsius annealing temperature) to further stabilize its structure and reduce structural defects.

Due to the surface plasmon polaritons and Tamm plasmon polaritons formed by the aluminum nanoparticles on the crystal, as well as the optical Tamm state resulting from their mutual resonance, the sensor structure accordingly completed by use of the aforementioned method effectively increases the sensitivity of chemical substance detection.

For example, if the present invention is to be used in the manufacturing of light-emitting diodes (LED), the forming steps of the microstructure 100 with high bonding strength are as follows:

1. A light-emitting diode containing P-type or N-type gallium nitride or aluminum indium gallium phosphide is taken as the substrate 10. Therein, the substrate 10 comprises the second dielectric layer 10b, which is a transparent conductive dielectric film containing indium tin oxide. The first surface 11 of the second dielectric layer 10b undergoes an annealing process (with a 550 degrees Celsius annealing temperature) to have its surface roughness reduced.

2. The substrate 10 is coated with nanoparticles of aluminum metal element or a nanoscale aluminum film as the deposition layer 20.

3. Parts of the deposition layer 20 are removed through a high-energy particle bombardment to form a transparent silicon dioxide insulating dielectric film, which is connected with the exposed area 112, as the first dielectric layer 30, thereby forming the microstructure 100 with high bonding strength.

4. The completed microstructure 100 with high bonding strength undergoes the heating process again (with a 100 degrees Celsius to 200 degrees Celsius heating temperature) to improve the bonding strength between the second dielectric layer 10b and the first dielectric layer 30, so as to further stabilize the structure of the completed microstructure 100 with high bonding strength and reduce its structural defects.

Due to the surface plasmon polaritons and the Tamm plasmon polaritons formed by the aluminum nanoparticles on the crystal, as well as the optical Tamm state resulting from their mutual resonance, the light emitting diode accordingly completed by use of the aforementioned method has its lighting efficiency effectively increased.

With the foregoing configuration and method, the present invention achieves following advantages.

The connection structure 50 between the first dielectric layer 30 and the exposed area 112 of the substrate 10 allows the hotspot structure 40 formed by the deposition layer 20 and the first dielectric layer 30 to be more stably fixed to the substrate 10. Also, due to the eutectic and bonding involving the nanoscale metal particles and the dielectric layer material, the connection structure 50 and the hotspot structure 40 are more stable, thereby achieving the objective of improving the bonding strength of the overall structure.

The connection structure 50 formed in the connection part between the first dielectric layer 30 and the exposed area 112 allows the structure of the present invention to have a higher structural strength and malleability.

The first dielectric layer 30 and the second dielectric layer 10b are allowed to be formed with same material, so that the first dielectric layer 30 and the second dielectric layer 10b have a higher bonding strength, further enhancing the structural strength of the present invention.

Through the surface plasmon polaritons and the Tamm plasmon polaritons formed by the nanoscale metal particles in the deposition layer 20 within the crystal, and the optical Tamm state resulting from their mutual resonance, the present invention effectively increases the efficiency in light emission or light detection sensitivity.

Using the gradient variation in the metal content caused by the covered area 111 and the exposed area 112, the primary generation areas of the surface plasmon polaritons and the Tamm plasmon polaritons are confined, and the framework of the hotspot structure 40 forms a more stable optical Tamm state. Also, the gradual decrease in the gradient of metal content within the hotspot structure 40 from the inside toward the outside allows a directional release of energy of the optical Tamm state from the areas with high metal content to those with low metal content, significantly reducing energy consumption caused by non-directionality, thereby maximizing the structural malleability.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A microstructure with high bonding strength, comprising:
a substrate having a first surface, the first surface having a covered area and an exposed area;
a deposition layer having a plurality of nanoscale metal particles, the deposition layer disposed on the covered area of the first surface, the exposed area exposed from the deposition layer, the deposition layer having a bonding face on one side thereof away from the first surface; and
a first dielectric layer disposed on the bonding face and contacting the exposed area.

2. The microstructure of claim 1, wherein the nanoscale metal particles are nanoscale metallic materials or metallic compound materials.

3. The microstructure of claim 1, wherein the nanoscale metal particles form a crystal themselves or in interaction with surrounding substance molecules; a surface plasmon polariton is generated on a surface of the nanoscale metal particles, and a Tamm plasmon polariton is formed at an interface or lattice discontinuity within the crystal; the surface plasmon polariton and the Tamm plasmon polariton resonate to create an optical Tamm state.

4. The microstructure of claim 1, wherein the nanoscale metal particles of the covered area form a hotspot structure with the first dielectric layer and the substrate through eutectic and bonding; the first dielectric layer of the exposed area contacts the substrate to form a connection structure.

5. The microstructure of claim 1, wherein the substrate comprises a substrate layer and a second dielectric layer; the second dielectric layer is disposed on one side of the substrate layer in adjacent to the deposition layer.

6. The microstructure of claim 5, wherein the second dielectric layer comprises a first surface on one side away from the substrate layer; the exposed area of the second dielectric layer is connected with the first dielectric layer.

7. The microstructure of claim 6, wherein the nanoscale metal particles of the covered area form a hotspot structure with the first dielectric layer and the second dielectric layer through eutectic and bonding; the first dielectric layer of the exposed area contacts the second dielectric layer to form a connection structure.

8. A method of forming a microstructure with high bonding strength, comprising:
a substrate providing step: providing a substrate, a first surface of the substrate having a covered area and an exposed area;
a deposition layer forming step: forming a deposition layer having a plurality of nanoscale metal particles on the covered area of the first surface, so that the exposed area is exposed from the deposition layer, wherein the deposition layer is formed through a method selected from a group consisting of spray coating, immersion coating, blade coating, roll coating, adsorption, and spin coating; and
a first dielectric layer forming step: forming a first dielectric layer on a bonding face of the deposition layer away from the first surface, so that the first dielectric layer is connected with the exposed area.

9. The method of claim 8, further comprising a reaction step, wherein in the reaction step, the nanoscale metal particles form a crystal themselves or in interaction with surrounding substance molecules; a surface plasmon polariton is generated on a surface of the nanoscale metal particles, and a Tamm plasmon polariton is formed at an interface or lattice discontinuity within the crystal; the surface plasmon polariton and the Tamm plasmon polariton resonate to create an optical Tamm state.

10. The method of claim 8, wherein in the first dielectric layer forming step, the nanoscale metal particles of the covered area form a hotspot structure with the first dielectric layer and the substrate through eutectic and bonding; the first dielectric layer of the exposed area contacts the substrate to form a connection structure.

11. The method of claim 8, wherein in the substrate providing step, the substrate comprises a substrate layer and a second dielectric layer; the second dielectric layer comprises the first surface on one side thereof away from the substrate layer.

12. The method of claim 11, wherein in the first dielectric layer forming step, the first dielectric layer is connected with the exposed area of the second dielectric layer.

13. The method of claim 12, wherein in the first dielectric layer forming step, the nanoscale metal particles of the covered area form a hotspot structure with the first dielectric layer and the second dielectric layer through eutectic and bonding; the first dielectric layer of the exposed area contacts the second dielectric layer to form a connection structure.

14. A method of forming a microstructure with high bonding strength, comprising:
a substrate providing step: providing a substrate, the substrate having a first surface;
a deposition layer forming step: forming a deposition layer having a plurality of nanoscale metal particles on the first surface of the substrate, wherein the deposition layer is formed through a method selected from a group consisting of physical vapor deposition and chemical vapor deposition; and
a first dielectric layer forming step: forming a first dielectric layer on a bonding face of the deposition layer away from the first surface, and forming an exposed area exposed from the deposition layer on the first surface through a high-energy destruction method, so that the first dielectric layer is connected with the exposed area.

15. The method of claim 14, further comprising a reaction step, wherein in the reaction step, the nanoscale metal particles form a crystal themselves or in interaction with surrounding substance molecules; a surface plasmon polariton is generated on a surface of the nanoscale metal particles, and a Tamm plasmon polariton is formed at an interface or lattice discontinuity within the crystal; the surface plasmon polariton and the Tamm plasmon polariton resonate to create an optical Tamm state.

16. The method of claim 14, wherein in the first dielectric layer forming step, the nanoscale metal particles of a covered area of the first surface form a hotspot structure with the first dielectric layer and the substrate through eutectic and bonding; the first dielectric layer of the exposed area contacts the substrate to form a connection structure.

17. The method of claim 14, wherein in the substrate providing step, the substrate comprises a substrate layer and a second dielectric layer; the second dielectric layer comprises the first surface on one side thereof away from the substrate layer.

18. The method of claim 17, wherein in the first dielectric layer forming step, the first dielectric layer is connected with the exposed area of the second dielectric layer.

19. The method of claim 18, wherein in the first dielectric layer forming step, the nanoscale metal particles of a covered area of the first surface form a hotspot structure with the first dielectric layer and the second dielectric layer through eutectic and bonding; the first dielectric layer of the exposed area contacts the second dielectric layer to form a connection structure.
